(19) United States
(12) Patent Application Publication
(10) Pub. No.: US 2025/0089250 A1
(43) Pub. Date: Mar. 13, 2025

(54) NONVOLATILE MEMORY CELL AND MANUFACTURING METHOD THEREOF

(71) Applicant: eMemory Technology Inc., Hsin-Chu (TW)

(72) Inventor: Wein-Town SUN, Hsinchu County (TW)

(21) Appl. No.: 18/830,613

(22) Filed: Sep. 11, 2024

Related U.S. Application Data
(60) Provisional application No. 63/537,860, filed on Sep. 12, 2023.

(51) Int. Cl. H10B 41/42; H10B 41/30

(52) U.S. Cl. CPC H10B 41/42; H10B 41/30

(57) ABSTRACT

A nonvolatile memory cell includes an N-well region, an IO gate dielectric layer, a floating gate dielectric layer, a floating gate layer, a first gate layer, a second gate layer and two p-doped regions. The floating gate dielectric layer is contacted with the surface of the N-well region. The floating gate layer covers the floating gate dielectric layer. The IO gate dielectric layer covers the surface of the N-well region and the floating gate layer. The first gate layer is contacted with IO gate dielectric layer located on the sidewall and the top surface of the floating gate layer. The second gate layer is contacted with the IO gate dielectric layer located on the sidewall of the floating gate layer. The first gate layer, the second gate layer and the floating gate layer are located over the surface of the N-well region between the two p-doped regions.

This application claims the benefit of U.S. provisional application Ser. No. 63/537,860, filed Sep. 12, 2023, the subject matters of which are incorporated herein by references.

### FIELD OF THE INVENTION

The present invention relates to a memory cell and a manufacturing method for the memory cell, and more particularly to a nonvolatile memory cell and a manufacturing method for the nonvolatile memory cell.

### BACKGROUND OF THE INVENTION

As is well known, a nonvolatile memory is able to continuously retain data after being power off. Consequently, nonvolatile memories have been widely applied to various electronic products. Generally, a nonvolatile memory comprises a peripheral circuit and a memory cell array. The peripheral circuit and the memory cell array are usually fabricated on the same semiconductor substrate. For example, the peripheral circuit comprises a bit line driver, a word line driver, a source line driver and a control unit. The memory cell array is composed of plural nonvolatile memory cells.

In the manufacturing process of the nonvolatile memory, the layout area of the semiconductor substrate is usually divided into a logic device area and a memory device area by the designer. The devices in the logic device area are collaboratively formed as the peripheral circuit of the nonvolatile memory. The devices in the memory device area are collaboratively formed as the memory cell array of the nonvolatile memory.

Generally, the devices in the logic device area are classified into input/output devices (or IO devices) and core devices. In addition, the devices in the memory device area are memory cells.

The core devices are also referred to as low voltage devices (or LV devices) such as LV P-type transistors and LV N-type transistors. The IO devices are also referred as high voltage devices (or HV devices) such as HV P-type transistors and HV N-type transistors. The LV device can withstand a low voltage stress. The HV device can withstand a higher voltage stress.

### SUMMARY OF THE INVENTION

An embodiment of the present invention provides a nonvolatile memory cell. The nonvolatile memory cell includes a semiconductor substrate, a well region, a first dielectric layer, a floating gate layer, a second dielectric layer, a first gate layer, a second gate layer, a first doped region, a second doped region, a first conducting line, a second conducting line, a third conducting line and a fourth conducting line. The well region is formed in the semiconductor substrate. The first dielectric layer is contacted with a surface of the well region. The floating gate layer covers the first dielectric layer. The second dielectric layer is contacted with the surface of the well region and a sidewall and a top side of the floating gate layer. An entire of the floating gate layer is covered by the first dielectric layer and the second dielectric layer. The first gate layer and the second gate layer are formed on the second dielectric layer. The first gate layer and the second gate layer are respectively located beside two sides of the floating gate layer. The first gate layer is contacted with the second dielectric layer on the sidewall and a top surface of the floating gate layer. The second gate layer is contacted with the second dielectric layer on the sidewall of the floating gate layer. A portion of the first gate layer and the floating gate layer are overlapped with each other. The first doped region and the second doped region are formed in the well region. The first gate layer, the second gate layer and the floating gate layer are located over the surface of the well region between the first doped region and the second doped region. The first conducting line is electrically connected with the first doped region. The second conducting line is electrically connected with the first gate layer. The third conducting line is electrically connected with the second gate layer. The fourth conducting line is electrically connected with the second doped region.

Another embodiment of the present invention provides a manufacturing method for a nonvolatile memory cell is provided. The manufacturing method includes the following steps. In a step (A), a first dielectric layer is formed on a surface of a semiconductor substrate. In a step (B), a floating gate layer is formed to cover the first dielectric layer. In a step (C), a second dielectric layer is formed on the surface of the semiconductor substrate. The second dielectric layer is contacted with a sidewall and a top side of the floating gate layer. In addition, an entire of the floating gate layer is covered by the first dielectric layer and the second dielectric layer. In a step (D), a first gate layer is formed on the second dielectric layer. The first gate layer is contacted with the second dielectric layer on the sidewall and a top surface of the floating gate layer. A portion of the first gate layer and the floating gate layer are overlapped with each other. In a step (E), a second gate layer is formed on the second dielectric layer. The second gate layer is contacted with the second dielectric layer on the sidewall of the floating gate layer, and the first gate layer and the second gate layer are respectively located beside two sides of the floating gate layer. A well region is formed in the semiconductor substrate. A first doped region and a second doped region are formed under a surface of the well region. The first gate layer, the second gate layer and the floating gate layer are located over the surface of the well region between the first doped region and the second doped region.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1J schematically illustrate the steps of a manufacturing method for a memory cell according to a first embodiment of the present invention;

FIG. 2A schematically illustrates the bias voltages for performing a program action on the memory cell Cell₁ according to the first embodiment of the present invention;

FIG. 2B schematically illustrates the bias voltages for performing an erase action on the memory cells Cell₁ and Cell₂ according to the first embodiment of the present invention;

FIG. 2C schematically illustrates the bias voltages for performing a read action on the memory cell Cell₁ according to the first embodiment of the present invention;

FIG. 2D schematically illustrates the bias voltages for performing a read action on the memory cell Cell₂ according to the first embodiment of the present invention;

FIGS. 3A to 3E schematically illustrate the steps of a manufacturing method for a memory cell according to a second embodiment of the present invention;

FIGS. 4A to 4D schematically illustrate the steps of a manufacturing method for a memory cell according to a third embodiment of the present invention;

FIGS. 5A to 5C schematically illustrate the steps of a manufacturing method for a memory cell according to a fourth embodiment of the present invention;

FIGS. 6A to 6H schematically illustrate the steps of a manufacturing method for a memory cell according to a fifth embodiment of the present invention;

FIGS. 7A to 7E schematically illustrate the steps of a manufacturing method for a memory cell according to a sixth embodiment of the present invention;

FIGS. 8A to 8E schematically illustrate the steps of a manufacturing method for a memory cell according to a seventh embodiment of the present invention; and

FIGS. 9A to 9E schematically illustrate the steps of a manufacturing method for a memory cell according to an eighth embodiment of the present invention.

### DETAILED DESCRIPTION OF PREFERRED EMBODIMENTS

The present invention provides a manufacturing method for a nonvolatile memory cell. By using the manufacturing method of the present invention, core devices, IO devices and memory cells can be fabricated on the same semiconductor substrate. That is, after the manufacturing method of the present invention is completed, the devices required to form a peripheral circuit and a memory cell array are fabricated on the same semiconductor substrate. Consequently, the nonvolatile memory with the peripheral circuit and the memory cell array is manufactured. Hereinafter, the nonvolatile memory cells are also referred to as memory cells.

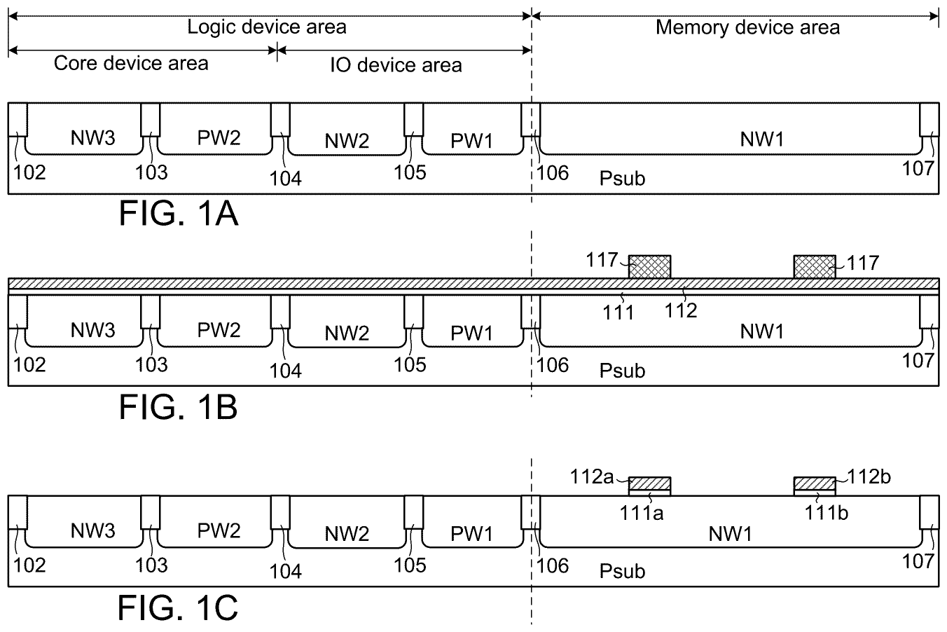

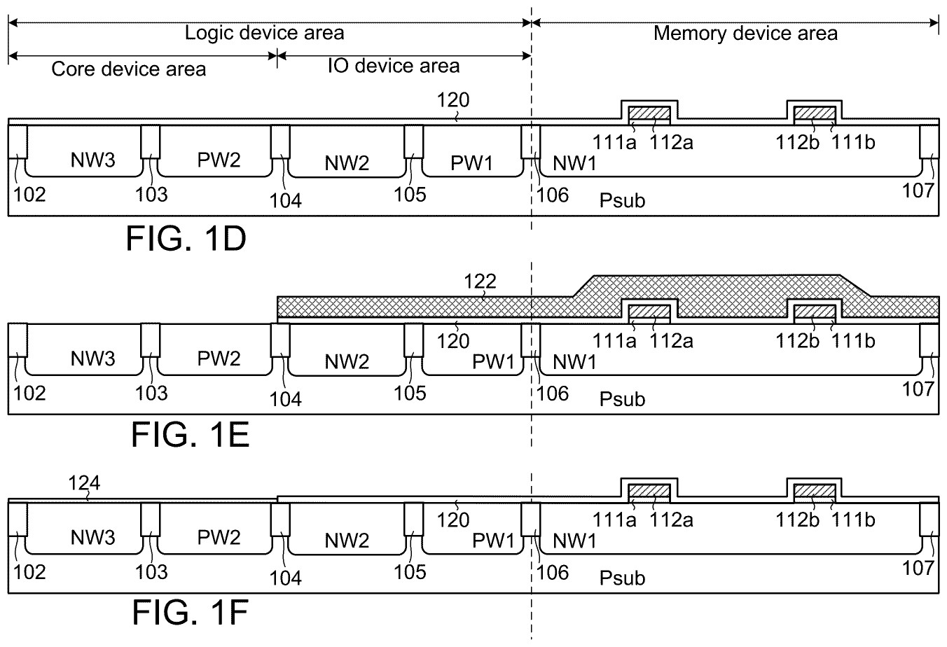

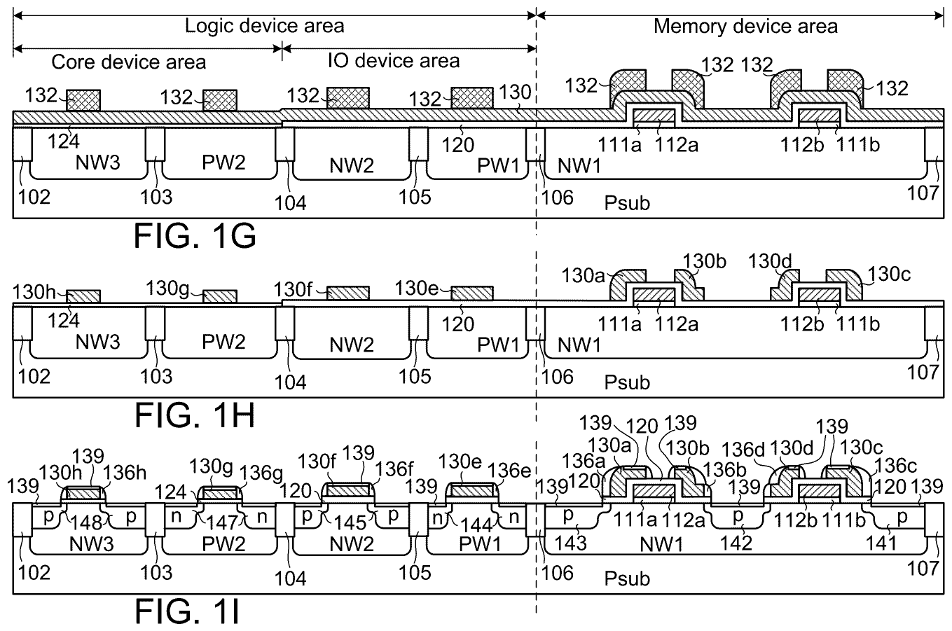

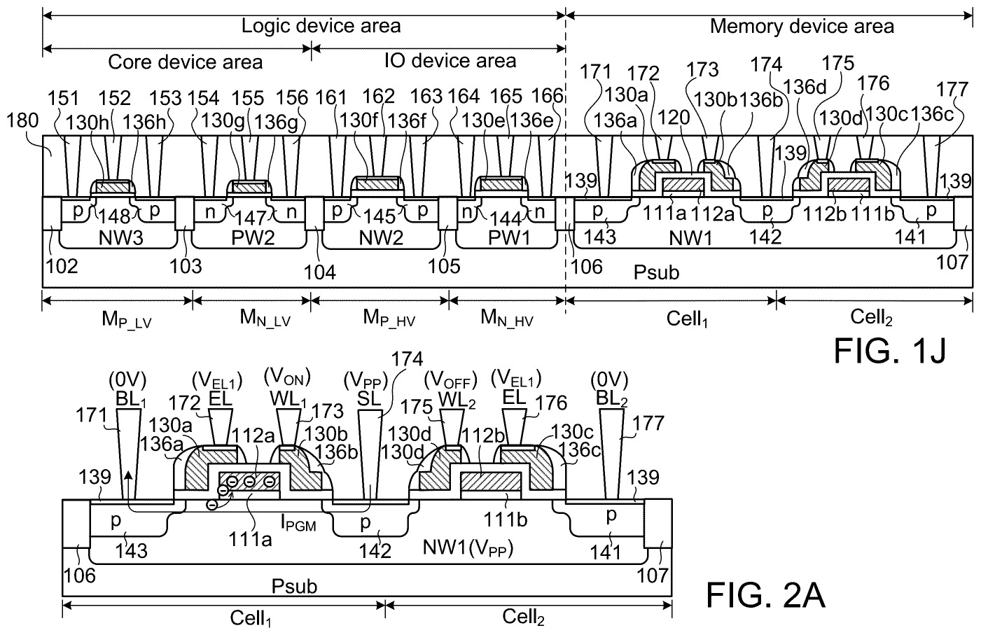

FIGS. 1A to 1J schematically illustrate the steps of a manufacturing method for a memory cell according to a first embodiment of the present invention.

As shown in FIG. 1A, an isolation structure formation process is performed. Firstly, plural isolation structures 102˜107 are formed in a semiconductor substrate Psub. For example, the semiconductor substrate Psub is a P-type substrate, and the isolation structures 102˜107 are shallow trench isolation (STI) structures.

Please refer to FIG. 1A again. On the surface of the semiconductor substrate Psub, the region between the isolation structure 102 and the isolation structure 106 is a logic device area, and the region between the isolation structure 106 and the isolation structure 107 is a memory device area. The devices in the logic device area are collaboratively formed as a peripheral circuit of the nonvolatile memory. The devices in the memory device area are collaboratively formed as a memory cell array of the nonvolatile memory.

Moreover, the logic device area is divided into an input/output device area (or an IO device area) and a core device area. As shown in FIG. 1A, the region between the isolation structure 104 and the isolation structure 106 is the IO device area, and the region between the isolation structure 102 and the isolation structure 104 is the core device area. The IO devices include HV P-type transistors and HV N-type transistors. The core devices include LV P-type transistors and LV N-type transistors.

In this embodiment, an HV N-type transistor will be formed in the region between the isolation structure 105 and the isolation structure 106, an HV P-type transistor will be formed in the region between the isolation structure 104 and the isolation structure 105, an LV N-type transistor will be formed in the region between the isolation structure 103 and the isolation structure 104, and an LV P-type transistor will be formed in the region between the isolation structure 102 and the isolation structure 103.

Then, plural well formation processes are performed. For example, after plural ion implantation processes are performed, an N-well region NW1 is formed under the surface of the semiconductor substrate Psub in the memory device area, and two N-well regions NW2 and NW3 and two P-well regions PW1 and PW2 are formed under the surface of the semiconductor substrate Psub in the logic device area.

Please refer to FIG. 1A again. The N-well region NW1 is arranged between the isolation structure 106 and the isolation structure 107. The N-well region NW2 is arranged between the isolation structure 104 and the isolation structure 105. The P-well region PW1 is arranged between the isolation structure 105 and the isolation structure 106. The N-well region NW3 is arranged between the isolation structure 102 and the isolation structure 103. The P-well region PW2 is arranged between the isolation structure 103 and the isolation structure 104.

Please refer to FIG. 1B. Then, a floating gate dielectric layer 111 and a floating gate layer 112 are formed on the surface of the semiconductor substrate Psub. Then, a photoresist layer 117 is formed in the memory device area to cover portions of the floating gate dielectric layer 111. For example, the floating gate dielectric layer 111 is made of silicon oxide, and the floating gate layer 112 is made of polysilicon.

In an embodiment, a sacrifice silicon oxide layer (not shown) is formed on the surface of the semiconductor substrate Psub before the well formation processes. After the well formation processes are completed, the sacrifice silicon oxide layer on the surface of the semiconductor substrate Psub is removed. Then, as shown in FIG. 1B, the floating gate dielectric layer 111 and the floating gate layer 112 are formed.

Please refer to FIG. 1C. Then, an etching process is performed. Consequently, the portions of the floating gate dielectric layer 111 and the floating gate layer 112 uncovered by the photoresist layer 117 are removed. After the photoresist layer 117 is removed, the remaining floating gate layers 112a and 112b are respectively served as the floating gates of two memory cells.

Please refer to FIG. 1D. Then, an IO gate dielectric layer 120 is formed on the exposed surface of the semiconductor substrate Psub and the sidewalls and the top sides of the floating gate layers 112a and 112b. Consequently, the entire of the floating gate layer 112a is covered by the corresponding floating gate dielectric layer 111a and the IO gate dielectric layer 120, and the entire of the floating gate layer 112b is covered by the corresponding floating gate dielectric layer 111b and the IO gate dielectric layer 120. For example, the IO gate dielectric layer 120 is made of silicon dioxide.

Please refer to FIG. 1E. Then, a photoresist layer 122 is provided to cover the memory device area and the IO device area. Then, an etching process is performed. Consequently, the portion of the IO gate dielectric layer 120 on the surface of the semiconductor substrate Psub and in the core device area is removed.

Please refer to FIG. 1F. The photoresist layer 122 is firstly removed. Then, a core gate dielectric layer 124 is formed on the surface of the semiconductor substrate Psub and in the core device area, and make the IO gate dielectric layer 120 a little thicker. That is to say, the thickness of the core gate dielectric layer 124 is thinner than the thickness of the IO gate dielectric layer 120.

Then, a gate structure formation process and plural doping processes will be performed. The gate structure formation process and the doping processes are compatible with the standard CMOS manufacturing process. The steps will be briefly described as follows.

Please refer to FIG. 1G. Then, a gate layer 130 is formed to cover the logic device area and the memory device area. That is, the IO gate dielectric layer 120 and the core gate dielectric layer 124 are covered by the gate layer 130. Then, a photoresist layer 132 is formed on the gate layer 130 to cover portions of the gate layer 130. For example, the gate layer 130 is made of polysilicon.

Please refer to FIG. 1H. Then, an etching process is performed. Consequently, the portion of the gate layer 130 uncovered by the photoresist layer 132 is removed. After the photoresist layer 132 is removed, plural gate layers 130a, 130b, 130c and 130d are formed in the memory device area, plural gate layers 130e and 130f are formed in the IO device area, and plural gate layers 130g and 130h are formed in the core device area.

In the memory device area, the gate layers 130a and 130b are formed on the IO gate dielectric layer 120 and respectively located beside twos sides of the floating gate layer 112a. The gate layer 130a is contacted with the IO gate dielectric layer 120 on the sidewall and the top surface of the floating gate layer 112a. That is, a portion of the gate layer 130a and the floating gate layer 112a are overlapped with each other. The gate layer 130b is at least contacted with the IO gate dielectric layer 120 on the sidewall of the floating gate layer 112a. In addition, a portion of the gate layer 130b and the floating gate layer 112a maybe slightly overlapped with each other. Similarly, a portion of the gate layer 130c and the floating gate layer 112b are overlapped with each other. Similarly, the gate layer 130d is at least contacted with the IO gate dielectric layer 120 on the sidewall of the floating gate layer 112b.

Please refer to FIG. 1I. Then, in the IO device area, two spacers 136e and 136f are respectively formed on the sidewalls of the gate layers 130e and 130f. Similarly, in the core device area, two spacers 136g and 136h are respectively formed on the sidewalls of the gate layers 130g and 130h. Similarly, in the memory device area, plural spacers 136a, 136b, 136c and 136d are respectively formed on the sidewalls of the gate layers 130a, 130b, 130c and 130d. While the spacers 136a˜136h are formed, the exposed IO gate dielectric layer 120 and the exposed core gate dielectric layer 124 on the surface of the semiconductor substrate Psub are etched and removed, and the surface of the semiconductor substrate Psub are exposed.

Then, plural doping processes are performed. In the IO device area, two n-doped regions 144 are formed in the P-well region PW1 and respectively located beside two sides of the gate layer 130e, and two p-doped regions 145 are formed in the N-well region NW2 and respectively located beside two sides of the gate layer 130f. In the core device area, two n-doped regions 147 are formed in the P-well region PW2 and respectively located beside two sides of the gate layer 130g, and two p-doped regions 148 are formed in the N-well region NW3 and respectively located beside two sides of the gate layer 130h. In the memory device area, the p-doped regions 141, 142 and 143 are formed in the N-well region NW1. The p-doped region 143 is located beside the gate layer 130a. The p-doped region 141 is located beside the gate layer 130c. The p-doped region 142 is located beside the gate layer 130b and the gate layer 130d. That is, the p-doped region 142 is arranged between the gate layer 130b and the gate layer 130d.

Furthermore, the doping processes are performed many times after or before the spacers 136a˜136h are performed. Optionally, the above-mentioned doping process further comprises a lightly doped drain process (also referred as an LDD process) and/or a halo implantation process. That is, each of the doped regions 141˜148 is selectively equipped with an LDD region and/or a halo region.

Furthermore, silicide layers 139 are formed on the exposed surfaces of the p-doped regions 141˜143, 148, 145, the n-doped regions 144, 147 and the gate layers 130a˜130h.

As shown in FIG. 1J, a conducting line process is performed. Firstly, an interlayer dielectric layer (also referred as an ILD layer) 180 is formed to cover the surface of the semiconductor substrate Psub, the gate layers 130a˜130h and the spacers 136a˜136h. Then, plural contact holes are formed in the ILD layer 180. After a metallic material is filled in the contact holes, plural conducting lines 151˜156, 161˜166 and 171˜177 are formed.

The conducting lines 171, 174 and 177 are respectively contacted with the silicide layers 139 on the p-doped regions 143, 142 and 141. The conducting line 172 is contacted with the silicide layer 139 on the gate layer 130a. The conducting line 173 is contacted with the silicide layer 139 on the gate layer 130b. The conducting line 175 is contacted with the silicide layer 139 on the gate layer 130d. The conducting line 176 is contacted with the silicide layer 139 on the gate layer 130c. In other words, the conducting lines 171, 174 and 177 are respectively electrically connected with the p-doped regions 143, 142 and 141, and the conducting lines 172, 173, 175 and 176 are respectively electrically connected with the four gate layers 130a, 130b, 130d and 130c.

Similarly, the conducting lines 151, 153, 161 and 163 are respectively electrically connected with the four p-doped regions 148 and 145, the conducting lines 154, 156, 164 and 166 respectively electrically connected with the four n-doped regions 144 and 147, and the conducting lines 152, 155, 162 and 165 respectively electrically connected with the gate layers 130h, 130g, 130f and 130e.

Please refer to FIG. 1J again. The P-well region PW1, the two n-doped regions 144 and the gate layer 130e are collaboratively formed as an HV N-type transistor M_{N_HV}. The N-well region NW2, the two p-doped regions 145 and the gate layer 130f are collaboratively formed as an HV P-type transistor M_{P_HV}. The P-well region PW2, the two n-doped regions 147 and the gate layer 130g are collaboratively formed as an LV N-type transistor M_{N_LV}. The N-well region NW3, the two p-doped regions 148 and the gate layer 130h are collaboratively formed as an LV P-type transistor M_{P_LV}. The N-well region NW1, the two p-doped regions 142, 143, the floating gate layer 112a and the gate layers 130a, 130b are collaboratively formed as a memory cell Cell₁. The N-well region NW1, the two p-doped regions 141, 142, the floating gate layer 112b and the gate layers 130c, 130d are collaboratively formed as another memory cell Cell₂.

In the memory cell Cell₁, the floating gate dielectric layer 111a is contacted with the surface of the N-well region NW1, the floating gate layer 112a covers the floating gate dielectric layer 111a, and the IO gate dielectric layer 120 covers the surface of the N-well region NW1 and the floating gate layer 112a. The gate layers 130a and 130b are formed over the IO gate dielectric layer 120. The gate layer 130a is contacted with the IO gate dielectric layer 120 on the sidewall and the top surface of the floating gate layer 112a. The gate layer 130b is at least contacted with IO gate dielectric layer 120 on the sidewall of the floating gate layer 112a. The p-doped regions 142 and 143 are formed under the surface of the N-well region NW1. The floating gate layer 112a and the gate layers 130a and 130b are formed over the surface of the N-well region NW1 and between the p-doped regions 142 and 143. The conducting line 171 is electrically connected with the p-doped region 143. The conducting line 172 is electrically connected with the gate layer 130a. The conducting line 173 is electrically connected with the gate layer 130b. The conducting line 174 is electrically connected with the p-doped region 142.

In the memory cell Cell₂, the floating gate dielectric layer 111b is contacted with the surface of the N-well region NW1, the floating gate layer 112b covers the floating gate dielectric layer 111b, and the IO gate dielectric layer 120 covers the surface of the N-well region NW1 and the floating gate layer 112b. The gate layers 130c and 130d are formed over the IO gate dielectric layer 120. The gate layer 130c is contacted with the IO gate dielectric layer 120 on the sidewall and the top surface of the floating gate layer 112b. The gate layer 130d is at least contacted with the IO gate dielectric layer 120 on the sidewall of the floating gate layer 112b. The p-doped regions 141 and 142 are formed under the surface of the N-well region NW1. The floating gate layer 112b and the gate layers 130c and 130d are formed over the surface of the N-well region NW1 and between the p-doped regions 141 and 142. The conducting line 177 is electrically connected with the p-doped region 141. The conducting line 176 is electrically connected with the gate layer 130c. The conducting line 175 is electrically connected with the gate layer 130d. The conducting line 174 is electrically connected with the p-doped region 142. Furthermore, the conducting line 171 is served as a bit line BL₁, the conducting line 177 is served as a bit line BL₂, the conducting line 174 is served as a source line SL, the conducting lines 172 and 176 are served as an erasure line EL, the conducting line 173 is served as a word line WL₁, and the conducting line 175 is served as a word line WL₂.

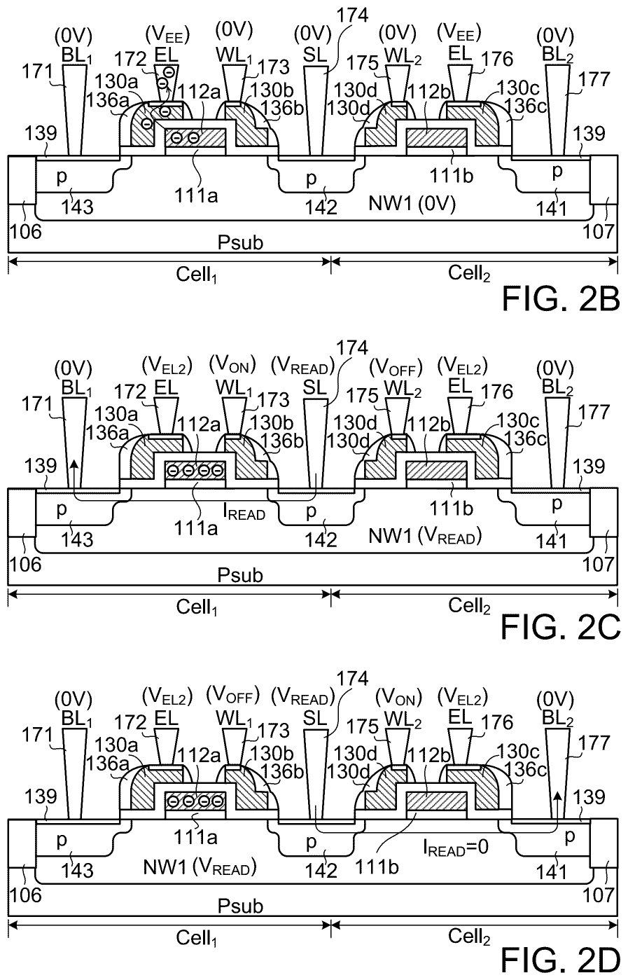

FIG. 2A schematically illustrates the bias voltages for performing a program action on the memory cell Cell₁ according to the first embodiment of the present invention. FIG. 2B schematically illustrates the bias voltages for performing an erase action on the memory cells Cell₁ and Cell₂ according to the first embodiment of the present invention. FIG. 2C schematically illustrates the bias voltages for performing a read action on the memory cell Cell₁ according to the first embodiment of the present invention. FIG. 2D schematically illustrates the bias voltages for performing a read action on the memory cell Cell₂ according to the first embodiment of the present invention.

Please refer to FIG. 2A. When the program action is performed on the memory cell Cell₁ and the program action is not performed on the memory cell Cell₂, an on voltage Von is provided to a word line WL₁, an off voltage V_{OFF} is provided to a word line WL₂, a program voltage V_{PP} is provided to a source line SL, a ground voltage (0V) is provided to the bit lines BL₁ and BL₂, and a first erase line voltage V_{EL1} is provided to an erase line EL. Moreover, the program voltage V_{PP} is provided to the N-well region NW1. For example, the on voltage Von is in a range between 0V and V_{PP}/2, the off voltage V_{OFF} is V_{PP}, and the program V_{PP} voltage is 7V. The first erase line voltage V_{EL1} is higher than or equal to the ground voltage (0V). For example, the first erase line voltage V_{EL1} is in a range between 0V and V_{PP}. In an embodiment, when the program action is performed, the first erase line voltage V_{EL1} gradually increases. For example, the first erase line voltage V_{EL1} gradually increases from 0V to V_{PP} (7V).

Please refer to FIG. 2A again. In the memory cell Cell₁, the word line WL₁ receives the on voltage VON, and thus the channel region under the floating gate layer 112a is turned on. Consequently, a program current I_{PGN} is generated, and the program current I_{PGN} flows from the source line SL to the bit line BL₁. Under this circumstance, a channel hot hole induced hot electron injection effect (also referred as a CHHIHE effect) is generated in the channel region, and electrons are transferred through the floating gate dielectric layer 111a and injected into the floating gate layer 112a. Consequently, the memory cell Cell₁ is changed into a program state.

In the memory cell Cell₂, the word line WL₂ receives the off voltage V_{OFF}, and the channel region under the floating gate layer 112b cannot be turned on. Consequently, no program current is generated in the region between the source line SL and the bit line BL₂. Under this circumstance, the CHHIHE effect is not generated, and electrons are not injected into the floating gate layer 112b. Consequently, the memory cell Cell₂ is not programmed. That is, the memory cell Cell₂ is maintained in the original state (e.g., an erase state).

Please refer to FIG. 2B. When the erase action is performed on the memory cells Cell₁ and Cell₂, the ground voltage (0V) is provided to the word lines WL₁ and WL₂, the ground voltage (0V) is provided to the source line SL, the bit lines BL₁ and BL₂, and an erase voltage V_{EE} is provided to the erase line EL. Moreover, the ground voltage (0V) is provided to the N-well region NW1. For example, the erase voltage V_{EE} is 12V.

Please refer to FIG. 2B again. In the memory cell Cell₁, the erase line EL receives the erase voltage V_{EE}, and a Fowler-Nordheim tunneling effect (also referred as a FN tunneling effect) is generated in the region between the floating gate layer 112a and the gate layer 130a. Consequently, electrons are ejected from the floating gate layer 112a to the erase line EL through the IO dielectric layer 120. Under this circumstance, the memory cell Cell₁ is changed into the erase state. In the memory cell Cell₂, electrons are not stored in the floating gate layer 112b, and thus the FN tunneling effect is not generated. Consequently, the memory cell Cell₂ is maintained in the erase state.

In the first embodiment, a portion of the gate layer 130a and a portion of the floating gate layer 112a are overlapped with each other. When the erase action is performed, a point discharge effect is generated. Due to the point discharge effect, electrons are ejected from the corner of the floating gate layer 112a to the erase line EL easily.

Generally, when the read action is performed, a read current IREAD is generated. The magnitude of the read currents IREAD is determined according to the result of judging whether electrons are stored in the floating gate layers 112a and 112b. According to the magnitudes of the read current IREAD, the storage state of the memory cells Cell and Cell₂ can be judged.

Please refer to FIG. 2C. When read action is performed on the memory cell Cell₁, the on voltage Von is provided to the word line WL₁, the off voltage V_{OFF} is provided to the word line WL₂, the read voltage VREAD is provided to the source line SL, the ground voltage (0V) is provided to the bit lines BL₁ and BL₂, and a second erase line voltage V_{EL2} is provided to the erase line EL. Moreover, the read voltage VREAD is provided to the N-well region NW1. For example, the on voltage Von is 0V, the off voltage V_{OFF} is VREAD, and the read voltage VREAD is 2V. The second erase line voltage V_{EL2} is higher than or equal of the ground voltage (0V). For example, the second erase line voltage V_{EL2} is in arranged between 0V and VREAD.

Please refer to FIG. 2C again. Since electrons are stored in the floating gate layer 112a of the memory cell Cell₁, a channel region is formed under the floating gate layer 112a. When the word line WL₁ receives the on voltage VON, the higher read current IREAD is generated by the memory cell Cell₁. The read current IREAD flows from the source line SL to the bit line BL₁. According to the magnitude of the read current IREAD, it is determined that the memory cell Cell₁ is in the program state.

Please refer to FIG. 2D. When the read action is performed on the memory cell Cell₂, the on voltage Von is provided to the word line WL₂, and the off voltage V_{OFF} is provided to the word line WL₁. The other bias voltages are similar to those shown in FIG. 2C.

Since no electrons are stored in the floating gate layer 112b of the memory cell Cell₂, the channel region cannot be formed under the floating gate layer 112b. When the word line WL₂ receives the on voltage Von, since the channel is not formed, the read current IREAD generated by the memory cell Cell₂ is very small (e.g. nearly zero). According to the magnitude of the read current IREAD, it is determined that the memory cell Cell₂ is in the erase state.

In the memory cells Cell₁ and Cell₂ of the first embodiment, the upper corners of the floating gate layers 112a and 112b are right-angled corners. When the erase action is performed, electrons are ejected from the corner of the floating gate layer 112a to the erase line EL in response to the point discharge effect. It is noted that the manufacturing method may be further modified. For example, by referring to the manufacturing method of the first embodiment, the upper corners of the floating gates of the memory cells are acute corners. Since electrons can be injected from the corner of the floating gate layer to the erase line EL more easily, the program efficiency of the memory cell is enhanced.

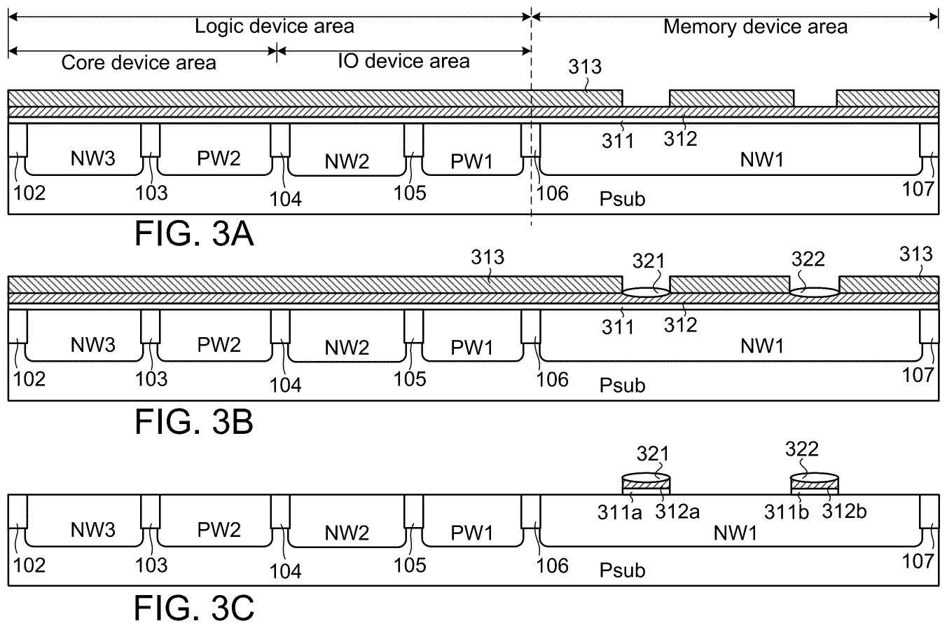

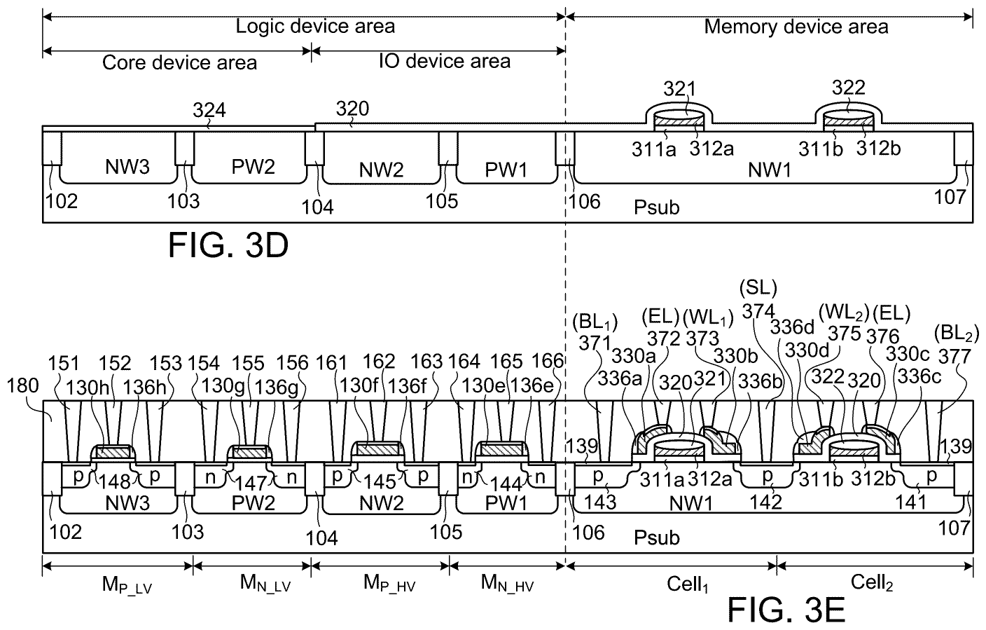

FIGS. 3A to 3E schematically illustrate the steps of a manufacturing method for a memory cell according to a second embodiment of the present invention. Firstly, the step as shown in FIG. 1A is performed. The subsequent steps of the second embodiment will be described as follows.

Please refer to FIG. 3A. Then, a floating gate dielectric layer 311, a floating gate layer 312 and a SiN layer 313 are formed on the surface of the semiconductor substrate Psub. Then, the SiN layer 313 is etched. In addition, two openings are formed in the memory device area. Consequently, the floating gate layer 312 is exposed through the two openings. The floating gate layer 312 is made of polysilicon.

Please refer to FIG. 3B. Then, a thermal oxidation process is performed. During the thermal oxidation process, the oxidation rate of the floating gate layer 312 beside the peripheries of the openings of the SiN layer 313 is slower, and the oxidation rate of the floating gate layer 312 beside the middle regions of the openings of the SiN layer 313 is faster. Consequently, two tip-shaped dielectric layers 321 and 322 are formed. The tip-shaped dielectric layers 321 and 322 are made of silicon dioxide.

Please refer to FIG. 3C. The SiN layer 313 is removed by performing a wet etching process. Then, by adjusting polysilicon and oxide etching rate, it is able to get fast polysilicon etching rate and much slow oxide etching rate. That is, the two tip-shaped dielectric layers 321 and 322 can be used as hard mask to selectively etch the floating gate layer 312 and the floating gate dielectric layer 311. After polysilicon etching and oxide etching are performed. The floating gate layer 312 and the floating gate dielectric layer 311 out of the two tip-shaped dielectric layers 321 and 322 area is removed as shown FIG. 3C. The underlying floating gate dielectric layers 311a and 311b and the floating gate layer 312a and 312b are retained. As shown in FIG. 3C, the remaining floating gate layers 312a and 312b are respectively served as the floating gates of two memory cells. In addition, the corners of the floating gate layers 312a and 312b are acute corners.

Please refer to FIG. 3D. An IO gate dielectric layer 320 is formed in the IO device area and the memory device area, and a core gate dielectric layer 324 is formed in the core device area. The IO gate dielectric layer 320 is formed on the surface of the semiconductor substrate Psub. In addition, the IO gate dielectric layer 320 is formed on the sidewall of the floating gate layers 312a and 312b and the top sides of the tip-shaped dielectric layers 321 and 322. Consequently, the entire of the floating gate layer 312a and the entire of the floating gate layer 312b are covered. In the second embodiment, the dielectric layer over the floating gate layer 312a is a merged dielectric layer. The merged dielectric layer is a stack structure of two sub-dielectric layers. That is, the dielectric layer over the floating gate layer 312a is a stack structure of the tip-shaped dielectric layer 321 and the IO gate dielectric layer 320. Similarly, the dielectric layer over the floating gate layer 312b is a stack structure of the tip-shaped layer 322 and the IO gate dielectric layer 320.

Moreover, the subsequent steps for manufacturing the memory cell of the second embodiment are identical to the steps shown in FIGS. 1G to 1J, and not redundantly described herein. That is, the resulting structure shown in FIG. 3D is then subjected to the gate structure formation process, the doping processes, the spacer formation process, the silicide layer formation process and the conducting line process. Consequently, plural gate layers 330a, 330b, 330c and 330d, plural spacers 336a, 336b, 336c and 336d, a silicide layer 139 and plural conducting lines 371˜377 are formed in the memory device area.

Consequently, as shown in FIG. 3E, an HV N-type transistor M_{N_HV}, an HV P-type transistor M_{P_HV}, an LV N-type transistor M_{N_LV}, an LV P-type transistor M_{P_LV} and two memory cells Cell₁, Cell₂ are formed on the semiconductor substrate. Moreover, the conducting lines 371 and 377 are respectively served as a bit line BL₁ and a bit line BL₂, the conducting line 371 is served as a source line SL, the conducting lines 372 and 376 are served as an erase line EL, the conducting line 373 is served as a word line WL₁, and the conducting line 375 is served as a word line WL₂.

In comparison with the memory cells Cell₁ and Cell₂ of the first embodiment, the dielectric layers over the floating gate layers 312a and 312b of the memory cells Cell₁ and Cell₂ shown in FIG. 3E are merged dielectric layers. The merged dielectric layer is a stack structure of two sub-dielectric layers. In addition, the corner of the floating gate layer 312a beside the gate layer 330a is an acute corner. Similarly, the corner of the floating gate layer 312b beside the gate layer 330c is an acute corner.

In the memory cell Cell₁ of the first embodiment, the region between the two p-doped regions 142 and 143 is a channel region. In order to shorten the length of the channel region, the manufacturing method may be further modified. When the program action is performed, electrons can be injected from the channel region into the floating gate layer more easily. Consequently, the program efficiency of the memory cell is enhanced.

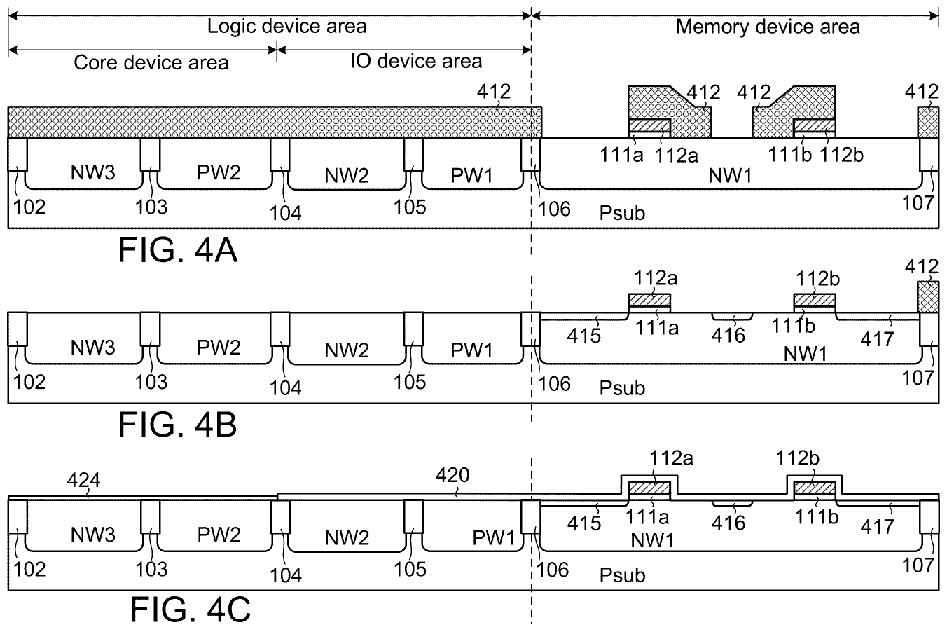

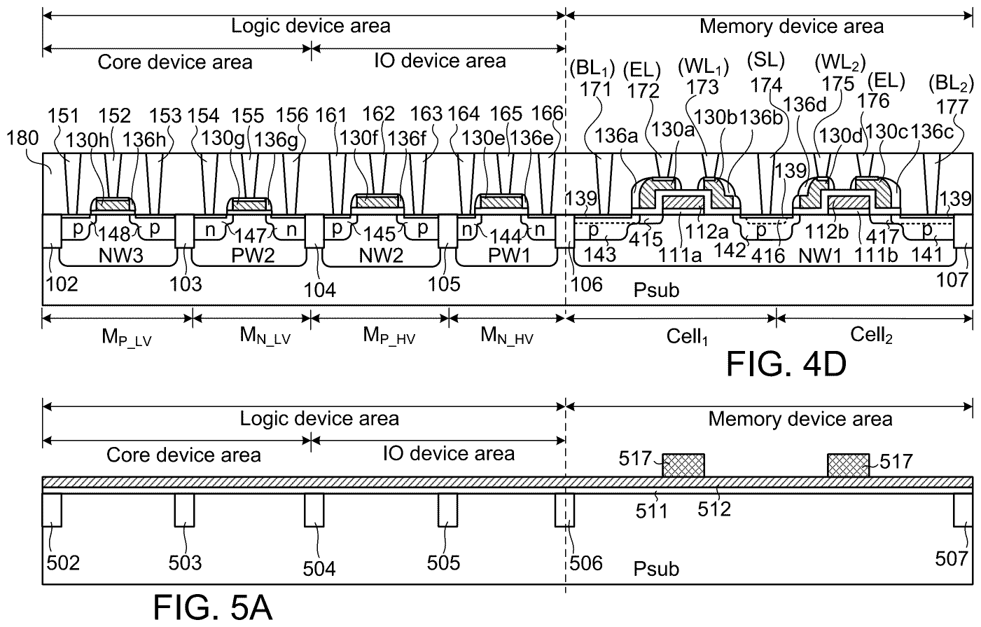

FIGS. 4A to 4D schematically illustrate the steps of a manufacturing method for a memory cell according to a third embodiment of the present invention. Firstly, the step as shown in FIG. 1C is performed. The subsequent steps of the third embodiment will be described as follows.

The Please refer to FIG. 4A. A photoresist layer 412 is formed to cover the semiconductor substrate Psub and the floating gate layers 112a and 112b. In addition, the surface of the semiconductor substrate Psub in the memory device area is exposed.

After a lightly doped drain formation process (also referred as an LDD formation process) is performed, and then the photoresist layer 412 is removed. As shown in FIG. 4B, three p-LDD regions 415, 416 and 417 are formed under the surface of the N-well region NW1. The p-LDD region 415 is located beside a first side of the floating gate layer 112a. The p-LDD region 417 is located beside a first side of the floating gate layer 112b. The p-LDD region 416 is arranged between a second side of the floating gate layer 112a and a second side of the floating gate layer 112b.

Please refer to FIG. 4C. Then, an IO gate dielectric layer 420 is formed in the IO device area and the memory device area, and a core gate dielectric layer 424 is formed in the core device area. The IO gate dielectric layer 420 is formed on the surface of the semiconductor substrate Psub. In addition, IO gate dielectric layer 420 covers the sidewalls and the tops sides of the floating gate layers 112a and 112b. Consequently, the entire of the floating gate layer 112a and the entire of the floating gate layer 112b are covered.

Moreover, the subsequent steps for manufacturing the memory cell of the third embodiment are identical to the steps shown in FIGS. 1G to 1J, and not redundantly described herein. That is, the resulting structure shown in FIG. 4C is then subjected to the gate structure formation process, the doping processes, the spacer formation process, the silicide layer formation process and the conducting line process. Consequently, as shown in FIG. 4D, an HV N-type transistor M_{N_HV}, an HV P-type transistor M_{P_HV}, an LV N-type transistor M_{N_LV}, an LV P-type transistor M_{P_LV} and two memory cells Cell₁, Cell₂ are formed on the semiconductor substrate.

In comparison with the structure in FIG. 1J and the structure in FIG. 4D, the structures of the doped regions in the memory cells Cell₁ and Cell₂ are different. The other structures are identical, and not redundantly described herein. In the memory cells Cell₁ and Cell₂ shown in FIG. 4D, the p-doped region 141 and the p-LDD region 417 are collaboratively formed as a first merged doped region. The p-doped region 143 and the p-LDD region 145 are collaboratively formed as a second merged doped region. The p-doped region 142 and the p-LDD doped region 416 are collaboratively formed as a third merged doped region. For example, the p-doped region 143 and an extended doped region are collaboratively formed as the first merged doped region. The extended doped region is located under the surface of the N-well region NW1 and extended from a side of the gate layer 130a to an underlying region of the gate layer 130a. Similarly, the p-doped region 141 and another extended doped region are collaboratively formed as the second merged doped region. The extended doped region is located under the surface of the N-well region NW1 and extended from a side of the gate layer 130c to the underlying region of the gate layer 130c.

It is noted that the memory cells Cell₁ and Cell₂ of the third embodiment may be further modified. For example, the floating gate layers 112a and 112b in the memory cells Cell₁ and Cell₂ of the third embodiment have the acute corners.

In comparison with the first embodiment, the lengths of the channel regions in the memory cells Cell₁ and Cell₂ of the third embodiment are shorter. When the program action is performed, electrons can be injected from the channel region into the floating gate layer more easily. Consequently, the program efficiency of the memory cell is enhanced.

In the above three embodiments, the floating gate layers of the memory cells Cell₁ and Cell₂ are formed after the isolation structure formation process and the well region formation processes are completed. It is noted that the manufacturing method may be modified. For example, in other embodiments, the floating gate layers of the memory cells Cell₁ and Cell₂ are formed before the isolation structure formation process or the well region formation process is completed. The associated procedures will be described as follows.

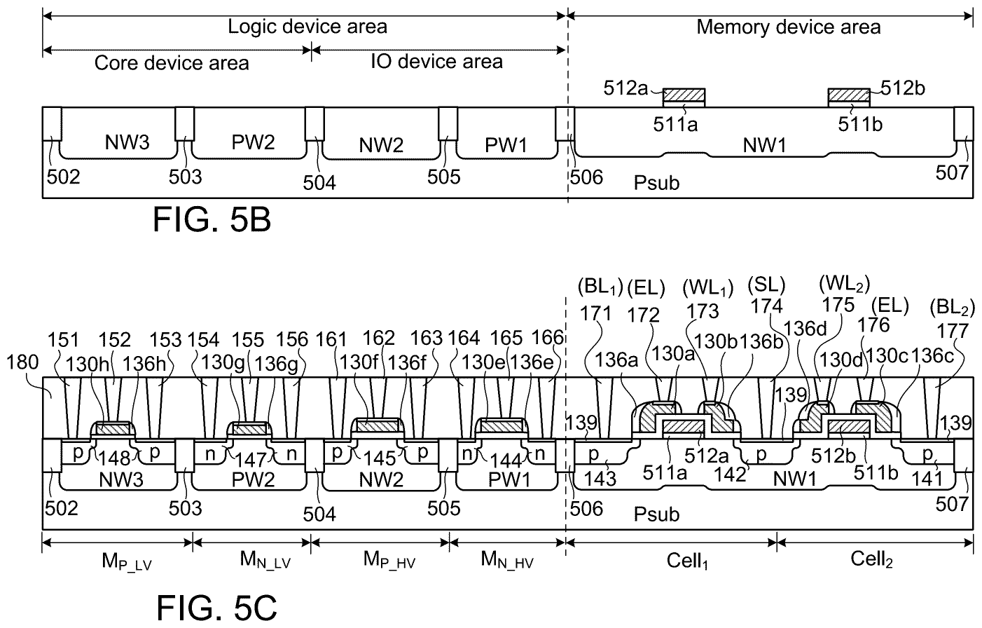

FIGS. 5A to 5C schematically illustrate the steps of a manufacturing method for a memory cell according to a fourth embodiment of the present invention.

As shown in FIG. 5A, an isolation structure formation process is performed on the semiconductor substrate Psub. Consequently, plural isolation structures 502˜507 are formed in the semiconductor substrate Psub. Then, a floating gate dielectric layer 511 and a floating gate layer 512 are formed on the surface of the semiconductor substrate Psub. Then, a photoresist layer 517 is formed in the memory device area. In addition, portions of the floating gate layer 512 are covered by the photoresist layer 517.

Please refer to FIG. 5B. Then, an etching process is performed. Consequently, the portions of the floating gate dielectric layer 511 and the floating gate layer 512 uncovered by the photoresist layer 517 are removed. After the photoresist layer 517 is removed, the remaining floating gate layers 512a and 512b are respectively served as the floating gates of two memory cells.

Then, plural well formation processes are performed. For example, after plural ion implantation processes are performed, an N-well region NW1 is formed under the surface of the semiconductor substrate Psub and in the memory device area, and two N-well regions NW2 and NW3 and two P-well regions PW1 and PW2 are formed under the surface of the semiconductor substrate Psub and in the logic device area.

In the fourth embodiment, the floating gate layers 512a and 512b have been formed on the surface of the semiconductor substrate Psub before the well formation process is completed. Consequently, as shown in FIG. 5B, the N-well region NW1 under the floating gate layers 512a and 512b is shallower after the well formation process is completed. However, the operations of the memory cell are not adversely affected.

The resulting structure shown in FIG. 5B is similar to the resulting structure shown in FIG. 1C. Consequently, the subsequent steps for manufacturing the memory cell of the fourth embodiment are identical to the steps shown in FIGS. 1D to 1J, and not redundantly described herein. That is, the resulting structure shown in FIG. 5B is then subjected to the IO gate dielectric layer formation process, the core gate dielectric layer formation process, the gate structure formation process, the doping processes, the spacer formation process, the silicide layer formation process and the conducting line process. Consequently, as shown in FIG. 5C, an HV N-type transistor M_{N_HV}, an HV P-type transistor M_{P_HV}, an LV N-type transistor M_{N_LV}, an LV P-type transistor M_{P_LV} and two memory cells Cell₁, Cell₂ are formed on the semiconductor substrate.

In comparison with the memory cells Cell₁ and Cell₂ of the first embodiment in FIG. 1J, only the shape of the N-well region NW1 in the memory cells Cell₁ and Cell₂ is distinguished. The other structures of the fourth embodiment are identical to the structures shown in FIG. 1J, and not redundantly described herein.

Moreover, when the well formation process is performed, a sacrifice silicon oxide layer is formed on the surface of the semiconductor substrate Psub. After the well formation processes are completed, the sacrifice silicon oxide layer on the surface of the semiconductor substrate Psub is removed. Actually, in the memory cells Cell₁ and Cell₂ of the fourth embodiment, the floating gate dielectric layers 511a and 511b underlying the floating gate layers 512a and 512b may be replaced by the sacrifice silicon oxide layer.

Similarly, in the memory cells Cell₁ and Cell₂ of the fourth embodiment, the upper corners of the floating gate layers 512a and 512b are right-angled corners. The manufacturing method of the fourth embodiment may be further modified. For example, by referring to the manufacturing method of the second embodiment, the upper corners of the floating gates of the memory cells are acute corners. Since electrons can be injected from the corner of the floating gate layer to the erase line EL more easily, the program efficiency of the memory cell is enhanced.

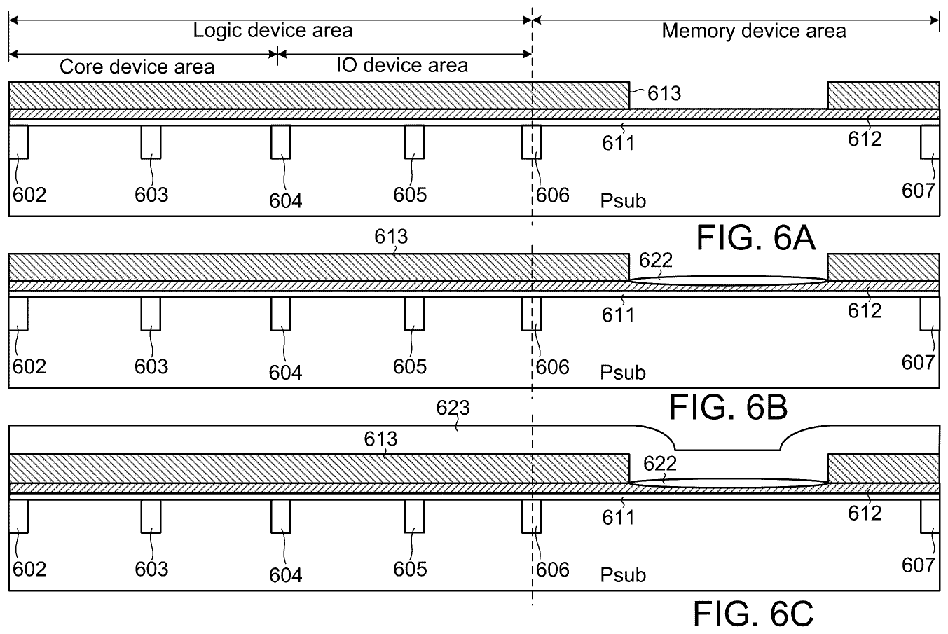

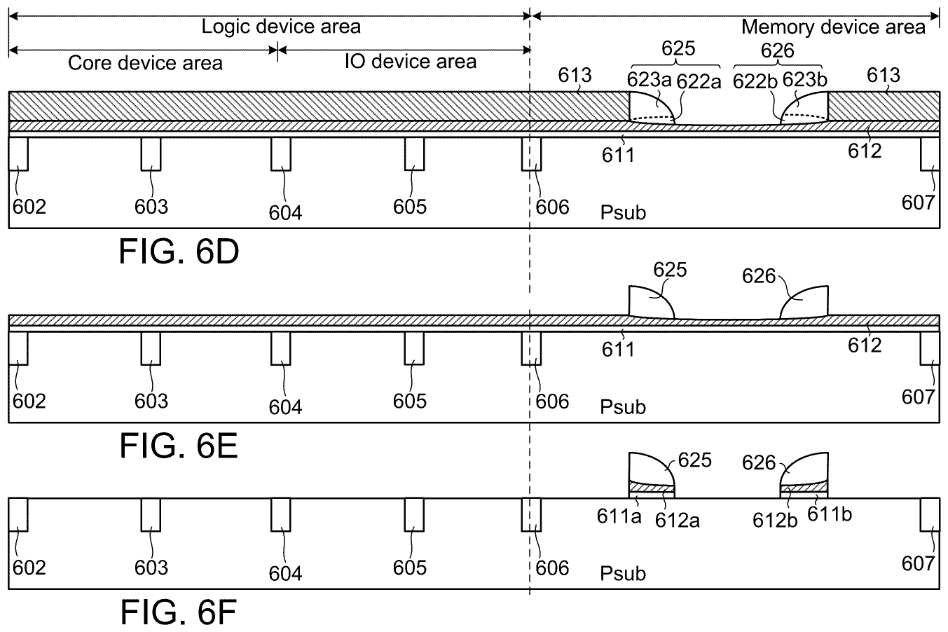

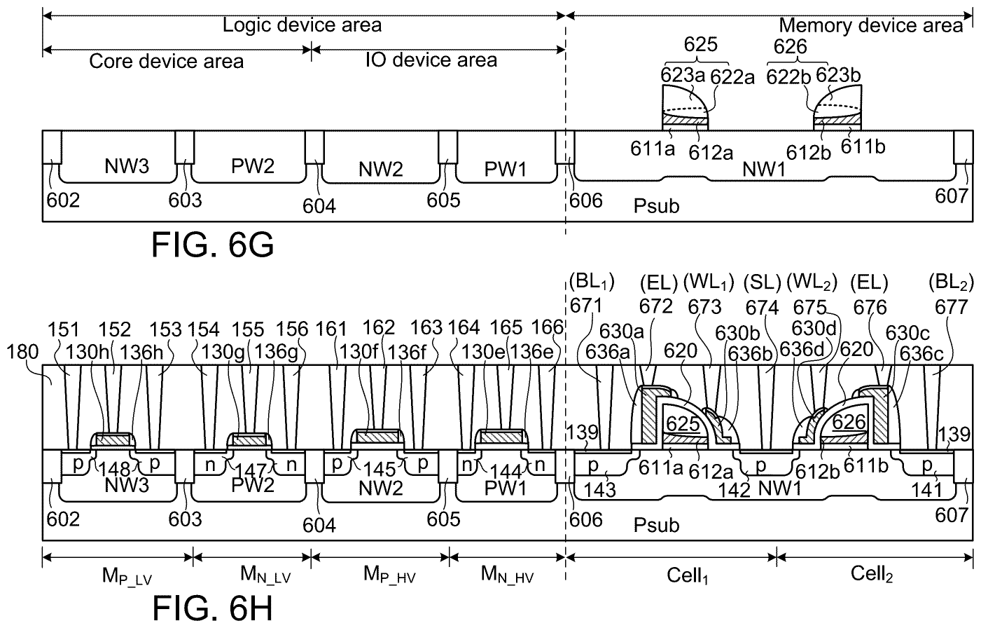

FIGS. 6A to 6H schematically illustrate the steps of a manufacturing method for a memory cell according to a fifth embodiment of the present invention.

As shown in FIG. 6A, an isolation structure formation process is performed on the semiconductor substrate Psub. Consequently, plural isolation structures 602˜607 are formed in the semiconductor substrate Psub. Then, a floating gate dielectric layer 611, a floating gate layer 612 and a SiN layer 613 are formed on the surface of the semiconductor substrate Psub. Then, the SiN layer 613 is etched. In addition, an opening is formed in the memory device area. Consequently, the floating gate layer 612 is exposed through the opening. The floating gate layer 612 is made of polysilicon.

Please refer to FIG. 6B. Then, a thermal oxidation process is performed. During the thermal oxidation process, the oxidation rate of the floating gate layer 612 beside the periphery of the opening of the SiN layer 613 is slower, and the oxidation rate of the floating gate layer 612 beside the middle region of the opening of the SiN layer 613 is faster. Consequently, a tip-shaped dielectric layers 622 is formed. The tip-shaped dielectric layers 622 is made of silicon dioxide.

Please refer to FIG. 6C. Then, a silicon dioxide layer 623 is deposited on the SiN layer 613 and the tip-shaped dielectric layer 622.

Please refer to FIG. 6D. Then, the silicon dioxide layer 623 and the tip-shaped dielectric layer 622 are etched. Consequently, in the memory device area, two remaining dielectric layers 625 and 626 are formed on the sidewall of the SiN layer 613. The remaining dielectric layer 625 contains a portion of the silicon dioxide layer 623a and a portion of the tip-shaped dielectric layer 622a. The remaining dielectric layer 626 contains a portion of the silicon dioxide layer 623b and a portion of the tip-shaped dielectric layer 622b.

As shown in FIG. 6E, the SiN layer 613 is removed. Please refer to FIG. 6F. Then, by adjusting polysilicon and oxide etching rate, it is able to get fast polysilicon etching rate and much slow oxide etching rate. That is, the remaining dielectric layers 625 and 626 can be used as hard mask to selectively etch floating gate layer 612 and floating gate dielectric layer 613. After polysilicon etching, oxide etching is performed. The floating gate layer 612 and the gate dielectric layer 611 out of the remaining dielectric layers 625 and 626 area is removed as shown in FIG. 6F. The remaining dielectric layers 625 and 626, the underlying floating gate dielectric layers 611a and 611b and the floating gate layer 612a and 612b are retained. As shown in FIG. 6F, the remaining floating gate layers 612a and 612b are respectively served as the floating gates of two memory cells. In addition, the corners of the floating gate layers 612a and 612b are acute corners.

Please refer to FIG. 6G. Then, plural well formation processes are performed. For example, after plural ion implantation processes are performed, an N-well region NW1 is formed under the surface of the semiconductor substrate Psub and in the memory device area, and two N-well regions NW2 and NW3 and two P-well regions PW1 and PW2 are formed under the surface of the semiconductor substrate Psub and in the logic device area.

Moreover, the resulting structures shown in FIG. 6G are similar to the resulting structures shown in FIGS. 1C and 5B. In comparison with the structures in FIGS. 1C and 5B, only the shapes of the floating gate layers 612a and 612b in the memory cells of this embodiment are distinguished, and the dielectric layers 625 and 626 are respectively formed on the floating gate layers 612a and 612b. Consequently, the subsequent steps for manufacturing the memory cell of the fifth embodiment are identical to the steps shown in FIGS. 1D to 1J, and not redundantly described herein. That is, the resulting structure shown in FIG. 6G is then subjected to the IO gate dielectric layer formation process, the core gate dielectric layer formation process, the gate structure formation process, the doping processes, the spacer formation process, the silicide layer formation process and the conducting line process. Consequently, plural gate layers 630a, 630b, 630c and 630d, plural spacers 636a, 636b, 636c and 636d, a silicide layer 139 and plural conducting lines 671˜677 are formed in the memory device area. As shown in FIG. 6H, an HV N-type transistor M_{N_HV}, an HV P-type transistor M_{P_HV}, an LV N-type transistor M_{N_LV}, an LV P-type transistor M_{P_LV} and two memory cells Cell₁, Cell₂ are formed on the semiconductor substrate. Moreover, the conducting lines 671 and 677 are respectively served as a bit line BL₁ and a bit line BL₂, the conducting line 674 is served as a source line SL, the conducting lines 672 and 676 are served as an erase line EL, the conducting line 673 is served as a word line WL₁, and the conducting line 675 is served as a word line WL₂.

In comparison with the memory cells Cell₁ and Cell₂ of the first embodiment, the dielectric layers over the floating gate layers 612a and 612b of the memory cells Cell₁ and Cell₂ shown in FIG. 6H are merged dielectric layers. The merged dielectric layer is a stack structure of three sub-dielectric layers. For example, the dielectric layer over the floating gate layer 612a comprises a portion of the tip-shaped dielectric layer 622a, a portion of the silicon dioxide layer 623a and an IO gate dioxide layer 620, which are stacked as the merged dielectric layer. The dielectric layer over the floating gate layer 612b comprises a portion of the tip-shaped dielectric layer 622b, a portion of the silicon dioxide layer 623b and an IO gate dioxide layer 620, which are stacked as the merged dielectric layer. In addition, the corner of the floating gate layer 612a beside the gate layer 630a is an acute corner. Similarly, the corner of the floating gate layer 612b beside the gate layer 630c is also an acute corner.

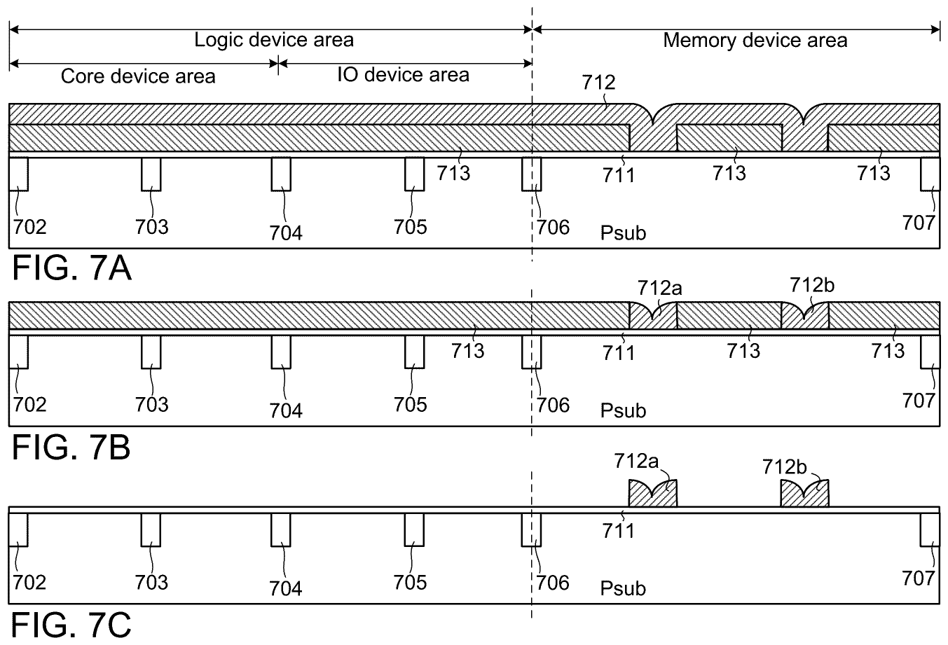

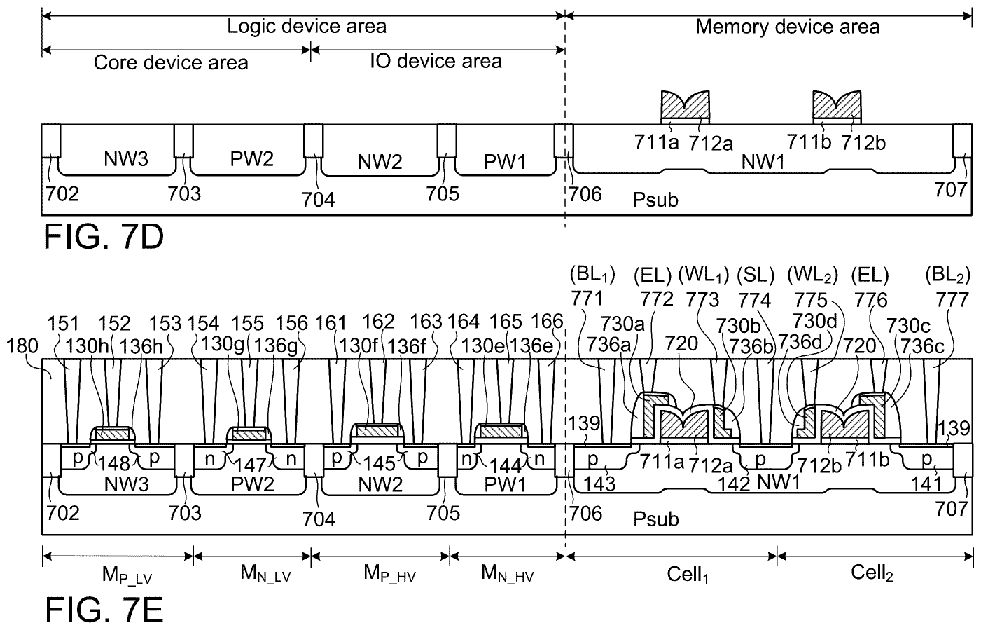

FIGS. 7A to 7E schematically illustrate the steps of a manufacturing method for a memory cell according to a sixth embodiment of the present invention.

As shown in FIG. 7A, an isolation structure formation process is performed on the semiconductor substrate Psub. Consequently, plural isolation structures 702˜707 are formed in the semiconductor substrate Psub. Then, a floating gate dielectric layer 711 and a SiN layer 713 are formed on the surface of the semiconductor substrate Psub. Then, the SiN layer 713 is etched. In addition, two openings are formed in the memory device area. Consequently, the floating gate dielectric layer 711 is exposed through the opening. Then, a floating gate layer 712 is formed to cover the floating gate dielectric layer 711 and the SiN layer 713. For example, the floating gate dielectric layer 711 is a pad oxide layer and the floating gate layer 712 is made of polysilicon.

Please refer to FIG. 7B. The floating gate layer 712 is etched. Consequently, in the memory device area, two remaining floating gate layers 712a and 712b are formed on the sidewall of the SiN layer 713. The remaining floating gate layers 712a and 712b are respectively served as the floating gates of two memory cells. In addition, the corners of the floating gate layers 712a and 712b are acute corners.

As shown in FIG. 7C, the SiN layer 713 is removed. Then, an oxide etching is performed. The floating gate dielectric layer 711 out of the remaining floating gate layers 712a and 712b area is removed and the floating gate dielectric layers 711a and 711b are retained as shown in FIG. 7D.

Please refer to FIG. 7D again. Plural well formation processes are performed. For example, after plural ion implantation processes are performed, an N-well region NW1 is formed under the surface of the semiconductor substrate Psub and in the memory device area, and two N-well regions NW2 and NW3 and two P-well regions PW1 and PW2 are formed under the surface of the semiconductor substrate Psub and in the logic device area.

Moreover, the structures shown in FIG. 7D are similar to the structures shown in FIGS. 1C and 5B. Consequently, the subsequent steps for manufacturing the memory cell of the sixth embodiment are identical to the steps shown in FIGS. 1D to 1J, and not redundantly described herein. That is, the resulting structure shown in FIG. 7D is then subjected to the IO gate dielectric layer formation process, the core gate dielectric layer formation process, the gate structure formation process, the doping processes, the spacer formation process, the silicide layer formation process and the conducting line process. Consequently, an IO gate dielectric layer 720, plural gate layers 730a, 730b, 730c and 730d, plural spacers 736a, 736b, 736c and 736d, a silicide layer 139 and plural conducting lines 771˜777 are formed in the memory device area. As shown in FIG. 7E, an HV N-type transistor M_{N_HV}, an HV P-type transistor M_{P_HV}, an LV N-type transistor M_{N_LV}, an LV P-type transistor M_{P_LV} and two memory cells Cell₁, Cell₂ are formed on the semiconductor substrate. Moreover, the conducting lines 771 and 777 are respectively served as a bit line BL₁ and a bit line BL₂, the conducting line 774 is served as a source line SL, the conducting lines 772 and 776 are served as an erase line EL, the conducting line 773 is served as a word line WL₁, and the conducting line 775 is served as a word line WL₂. In addition, the corner of the floating gate layer 712a beside the gate layer 730a is an acute corner. Similarly, the corner of the floating gate layer 712b beside the gate layer 730c is also an acute corner.

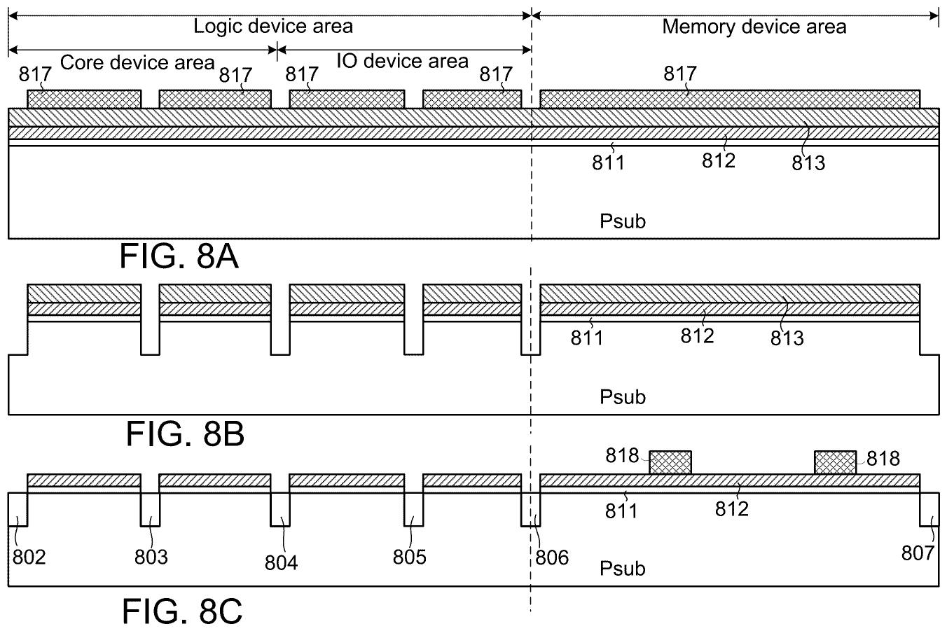

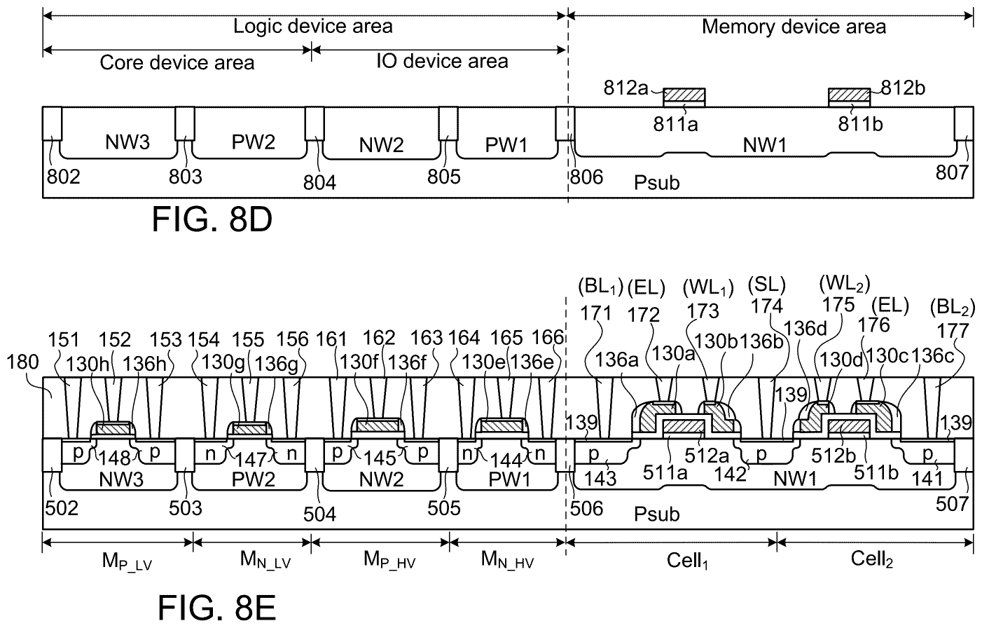

FIGS. 8A to 8E schematically illustrate the steps of a manufacturing method for a memory cell according to a seventh embodiment of the present invention.

As shown in FIG. 8A, an isolation structure formation process is performed on the semiconductor substrate Psub. Then, a floating gate dielectric layer 811, a floating gate layer 812, a SiN layer 813 and a photoresist layer 817 are formed on the surface of the semiconductor substrate Psub. In addition, plural openings are formed in the photoresist layer 817.

Please refer to FIG. 8B. Then, the portions of the SiN layer 813, the floating gate layer 812, the floating gate dielectric layer 811 and the semiconductor substrate Psub uncovered by the photoresist layer 817 are etched. In addition, plural concave regions are formed in the semiconductor substrate Psub.

Please refer to FIG. 8C. Then, plural isolation structures 802˜807 are formed in the plural concave regions of the semiconductor substrate Psub. After the SiN layer 813 is removed, a photoresist layer 818 is formed in the memory device area to cover portions of the floating gate layer 812.

Please refer to FIG. 8D. Then, the portions of the floating gate layer 812 and the floating gate dielectric layer 811 uncovered by the photoresist layer 818 are etched. After the photoresist layer 818 is removed, the remaining floating gate layers 812a and 812b are respectively served as the floating gates of two memory cells. After the photoresist layer 818 is removed, plural well formation processes are performed. That is, after plural ion implantation processes are performed, an N-well region NW1 is formed under the surface of the semiconductor substrate Psub and in the memory device area, and two N-well regions NW2 and NW3 and two P-well regions PW1 and PW2 are formed under the surface of the semiconductor substrate Psub and in the logic device area.

Moreover, the resulting structures shown in FIG. 8E are similar to the resulting structures shown in FIGS. 1C and 5B. Consequently, the subsequent steps for manufacturing the memory cell of the seventh embodiment are identical to the steps shown in FIGS. 1D to 1J, and not redundantly described herein.

In comparison with the memory cells Cell₁ and Cell₂ of the first embodiment shown in FIG. 1J, only the shape of the N-well region NW1 in the memory cells Cell₁ and Cell₂ is distinguished. The other structures of the seventh embodiment are identical to the structures shown in FIG. 1J, and not redundantly described herein.

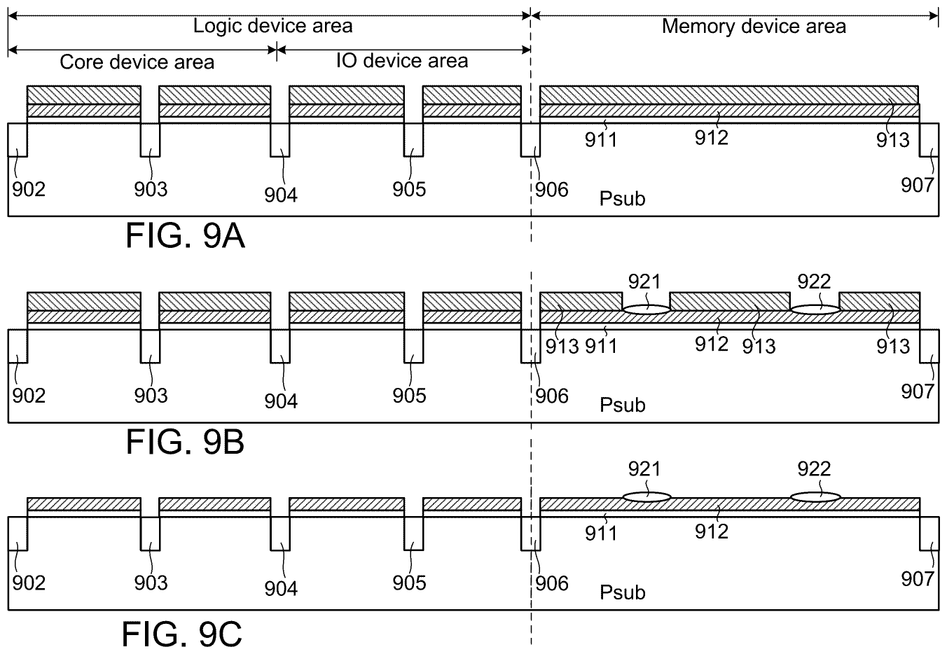

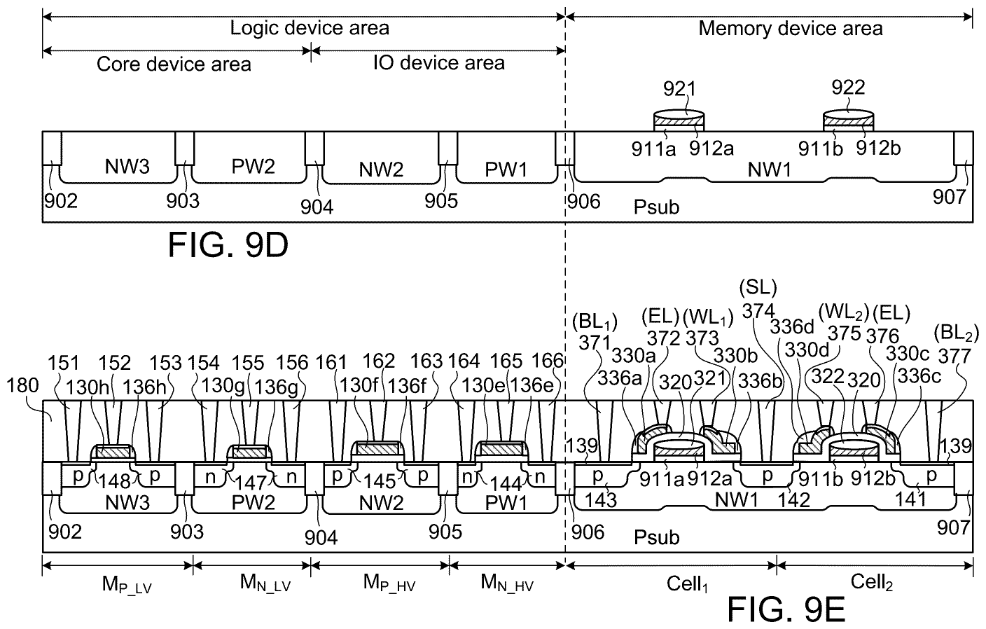

FIGS. 9A to 9E schematically illustrate the steps of a manufacturing method for a memory cell according to an eighth embodiment of the present invention.

As shown in FIG. 9A, an isolation structure formation process is performed on the semiconductor substrate Psub. Then, a floating gate dielectric layer 911, a floating gate layer 912 and a SiN layer 913 are formed on the surface of the semiconductor substrate Psub. In addition, plural openings are formed in the SiN layer 913. Then, the portions of the floating gate layer 912, the floating gate dielectric layer 911 and the semiconductor substrate Psub uncovered by the SiN layer 913 are etched. In addition, plural concave regions are formed in the semiconductor substrate Psub. Then, plural isolation structures 902˜907 are formed in the plural concave regions of the semiconductor substrate Psub. The floating gate layer 912 is made of polysilicon.

Please refer to FIG. 9B. Two openings are formed in the SiN layer 913 of the memory device area. Consequently, the floating gate layer 912 is exposed. Then, a thermal oxidation process is performed. During the thermal oxidation process, the oxidation rate of the floating gate layer 912 beside the periphery of the opening of the SiN layer 913 is slower, and the oxidation rate of the floating gate layer 912 beside the middle region of the opening of the SiN layer 913 is faster. Consequently, two tip-shaped dielectric layers 921 and 922 are formed. For example, the tip-shaped dielectric layers 921 and 922 are made of silicon dioxide.

Please refer to FIG. 9C, the SiN layer 913 is removed. Please refer to FIG. 9D. By adjusting polysilicon and oxide etching rate, it is able to get fast polysilicon etching rate and much slow oxide etching rate. Then, the two tip-shaped dielectric layers 921 and 922 can be used as hard mask to selectively etch the floating gate layer 912 and the floating gate dielectric layer 911. After polysilicon etching and oxide etching are performed. The floating gate layer 912 and the floating gate dielectric layer 911 out of the two tip-shaped dielectric layers 921 and 922 area is removed as shown in FIG. 9D, and the tip-shaped dielectric layers 921 and 922, the underlying floating gate dielectric layers 911a and 911b and the floating gate layer 912a and 912b are retained. As shown in FIG. 9D, the remaining floating gate layers 912a and 912b are respectively served as the floating gates of two memory cells. In addition, the corners of the floating gate layers 912a and 912b are acute corners.

Please refer to FIG. 9D again. Plural well formation processes are performed. For example, after plural ion implantation processes are performed, an N-well region NW1 is formed under the surface of the semiconductor substrate Psub and in the memory device area, and two N-well regions NW2 and NW3 and two P-well regions PW1 and PW2 are formed under the surface of the semiconductor substrate Psub and in the logic device area.

The resulting structure shown in FIG. 9D is similar to the resulting structure shown in FIG. 3D except that the IO gate dielectric layer and the core gate dielectric layer have not been formed in the structure of FIG. 9D. The subsequent steps for manufacturing the memory cell of the eighth embodiment are identical to the steps shown in FIGS. 1D to 1J, and not redundantly described herein.

In comparison with the memory cells Cell₁ and Cell₂ of the second embodiment shown in FIG. 3E, only the shape of the N-well region NW1 in the memory cells Cell₁ and Cell₂ is distinguished. The other structures of the eighth embodiment are identical to the structures shown in FIG. 1J, and not redundantly described herein.

From the above descriptions, the present invention provides the nonvolatile memory cell and the manufacturing method for the nonvolatile memory cell. In the above embodiments of the manufacturing method, the structures of the memory cells Cell₁ and Cell₂ may be further modified. For example, by referring to the manufacturing method of the third embodiment, the channel lengths of the memory cells Cell₁ and Cell₂ in the second embodiment, the fifth embodiment or the sixth embodiment may be changed to increase the program efficiency of the memory cells Cell₁ and Cell₂. The bias voltages for performing the program action, the erase action and the read action on the memory cells Cell₁ and Cell₂ are similar to those shown in FIGS. 2A to 2D, and not redundantly described herein.

Furthermore, the memory cells Cell₁ and Cell₂ described above are realized with P-type transistors (including the N-well region and the p-doped regions). Of course, the memory cells Cell₁ and Cell₂ of the present invention can also be realized with N-type transistors (including the P-well region and the n-doped regions). In comparison with the P-type transistors of the above embodiments, when the memory cells Cell₁ and Cell₂ are realized using the N-type transistors, the voltage condition during the program action can be adjusted to activate a channel hot electron injection effect (CHEI effect) or a source side hot electron injection effect (SSI effect) according the actual requirements. For example, when a program action is performed on the memory cell Cell₁, an on voltage VON (e.g. V_{PP}/8) is provided to a word line WL₁, a program voltage V_{PP} is provided to a bit line BL₁, a ground voltage (0V) is provided to the source line SL and the P-well region, and a erase line voltage VEL is provided to the erase line EL. In addition, the bias voltages for the erase action and the read action are similar to those in FIGS. 2B to 2D, and not redundantly described herein.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A nonvolatile memory cell, comprising:
a semiconductor substrate;
a well region formed in the semiconductor substrate;
a first dielectric layer contacted with a surface of the well region;
a floating gate layer covering the first dielectric layer;
a second dielectric layer contacted with and the surface of the well region, and contacted with a sidewall and a top side of the floating gate layer, wherein an entire of the floating gate layer is covered by the first dielectric layer and the second dielectric layer;
a first gate layer and a second gate layer formed on the second dielectric layer, wherein the first gate layer and the second gate layer are respectively located beside two sides of the floating gate layer, the first gate layer is contacted with the second dielectric layer on the sidewall and a top surface of the floating gate layer, the second gate layer is contacted with the second dielectric layer on the sidewall of the floating gate layer, and a portion of the first gate layer and the floating gate layer are overlapped with each other;
a first doped region and a second doped region formed under the surface of the well region, wherein the first gate layer, the second gate layer and the floating gate layer are located over the surface of the well region between the first doped region and the second doped region;
a first conducting line electrically connected with the first doped region;
a second conducting line electrically connected with the first gate layer;
a third conducting line electrically connected with the second gate layer; and
a fourth conducting line electrically connected with the second doped region.

2. The nonvolatile memory cell as claimed in claim 1, wherein a corner of the floating gate layer beside the first gate layer is a right-angled corner or an acute corner.

3. The nonvolatile memory cell as claimed in claim 1, wherein the second dielectric layer overlying the floating gate layer is a merged dielectric layer, and the merged dielectric layer is a stack structure of plural sub-dielectric layers.

4. The nonvolatile memory cell as claimed in claim 1, wherein the second dielectric layer is an input/output gate dielectric layer.

5. The nonvolatile memory cell as claimed in claim 1, wherein the first dielectric layer is a floating gate dielectric layer, a sacrifice silicon oxide layer or a pad oxide layer.

6. The nonvolatile memory cell as claimed in claim 1, wherein the first doped region and an extended doped region are collaboratively formed as a merged doped region, wherein the extended doped region is located under the surface of the well region, and the extended doped region extended from a side of the first gate layer to an underlying region of the first gate layer.

7. The nonvolatile memory cell as claimed in claim 1, wherein the first conducting line is a bit line, the second conducting line is an erase line, the third conducting line is a word line, and the fourth conducting line is a source line.

8. The nonvolatile memory cell as claimed in claim 7, wherein when a program action is performed, an on voltage is provided to the word line, a program voltage is provided to the source line, a ground voltage is provided to the bit line, and an erase line voltage is provided to the erase line, wherein when the program action is performed, a channel region under the floating gate layer is turned on, and a program current is generated, wherein the program current flows from the source line to the bit line through the channel region, and plural electrons are transferred through the first dielectric layer and injected into the floating gate layer.

9. The nonvolatile memory cell as claimed in claim 7, wherein when an erase action is performed, a ground voltage is provided to the word line, the source line and the bit line, and an erase voltage is provided to the erase line, so that plural electrons are ejected from the floating gate layer to the erase line through the second dielectric layer.

10. The nonvolatile memory cell as claimed in claim 7, wherein when a read action, an on voltage is provided to the word line, a read voltage is provided to the source line, a ground voltage is provided to the bit line, and an erase line voltage is provided to the erase line, wherein a storage state of the nonvolatile memory cell is determined according to a magnitude of a read current flowing from the source lien to the bit line.

11. A manufacturing method for a nonvolatile memory cell, the manufacturing method comprising steps of:
(A) forming a first dielectric layer on a surface of a semiconductor substrate;
(B) forming a floating gate layer to cover the first dielectric layer;
(C) forming a second dielectric layer on the surface of the semiconductor substrate, wherein the second dielectric layer is contacted with a sidewall and a top side of the floating gate layer, and an entire of the floating gate layer is covered by the first dielectric layer and the second dielectric layer;
(D) forming a first gate layer on the second dielectric layer, wherein the first gate layer is contacted with the second dielectric layer on the sidewall and a top surface of the floating gate layer, and a portion of the first gate layer and the floating gate layer are overlapped with each other; and
(E) forming a second gate layer on the second dielectric layer, wherein the second gate layer is contacted with the second dielectric layer on the sidewall of the floating gate layer, the first gate layer and the second gate layer are respectively located beside two sides of the floating gate layer,
wherein a well region is formed in the semiconductor substrate, a first doped region and a second doped region are formed under a surface of the well region, and the first gate layer, the second gate layer and the floating gate layer are located over the surface of the well region between the first doped region and the second doped region.

12. The manufacturing method as claimed in claim 11, further comprising a step (F) of forming a first conducting line, a second conducting line, a third conducting line and a fourth conducting line, wherein the first conducting line is electrically connected with the first doped region, the second conducting line is electrically connected with the first gate layer, the third conducting line is electrically connected with the second gate layer, and the fourth conducting line is electrically connected with the second doped region.

13. The manufacturing method as claimed in claim 12, wherein the first conducting line is a bit line, the second conducting line is an erase line, the third conducting line is a word line, and the fourth conducting line is a source line.

14. The manufacturing method as claimed in claim 11, further comprising a step of performing a thermal oxidation process on the floating gate layer, so that a corner of the floating gate layer beside the first gate layer is an acute corner.

15. The manufacturing method as claimed in claim 11, further comprising a step of performing an etching process, on the floating gate layer, so that a corner of the floating gate layer beside the first gate layer is an acute corner.

16. The manufacturing method as claimed in claim 11, wherein the second dielectric layer overlying the floating gate layer is a merged dielectric layer, and the merged dielectric layer is a stack structure of plural sub-dielectric layers.

17. The manufacturing method as claimed in claim 11, wherein the second dielectric layer is an input/output gate dielectric layer.

18. The manufacturing method as claimed in claim 11, wherein the first dielectric layer is a floating gate dielectric layer, a sacrifice silicon oxide layer or a pad oxide layer.

19. The manufacturing method as claimed in claim 11, further comprising a step of forming an extended doped region, wherein the first doped region and the extended doped region are collaboratively formed as a merged doped region, wherein the extended doped region is located under the surface of the well region, and the extended doped region extended from a side of the first gate layer to an underlying region of the first gate layer.

20. The manufacturing method as claimed in claim 11, wherein the well region is formed before or after the forming of the floating gate layer.
